(19) United States
(12) Patent Application Publication
(10) Pub. No.: US 2013/0171745 A1
(43) Pub. Date: Jul. 4, 2013

(54) ENERGY METER CALIBRATION AND MONITORING

(71) Applicant: Amikam Sade, Cupertino, CA (US)

(72) Inventor: Amikam Sade, Cupertino, CA (US)

(21) Appl. No.: 13/713,914

(22) Filed: Dec. 13, 2012

Related U.S. Application Data
(60) Provisional application No. 61/570,533, filed on Dec. 14, 2011.

(51) Int. Cl. H01L 21/66

(52) U.S. Cl. CPC H01L 22/26
USPC 438/5

(57) ABSTRACT

A method of controlling a thermal treatment process for semiconductor substrates is described. A substrate is disposed in a thermal process chamber. A plurality of test locations are identified on the substrate surface, and the test locations are processed with different combinations of energy fluence and exposure duration. A physical property such as reflectivity is measured for each test process, and the data compared to a standard data set. The performance of the process is thus compared to a known physical quantity, and an adjustment applied to correct performance of the thermal processing apparatus.

### CROSS-REFERENCE TO RELATED APPLICATIONS

This application claims benefit of U.S. Provisional Patent Application Ser. No. 61/570,533, filed Dec. 14, 2011, which is incorporated herein by reference.

### FIELD

Embodiments described herein relate to manufacture of semiconductor devices. More specifically, embodiments described herein relate to apparatus and methods for monitoring thermal processes.

### BACKGROUND

Thermal processing is commonly practiced in the semiconductor industry. Semiconductor substrates are subjected to thermal processing in the context of many transformations, including doping, activation, and annealing of gate source, drain, and channel structures, siliciding, crystallization, oxidation, and the like. Over the years, techniques of thermal processing have progressed from simple furnace baking to various forms of increasingly rapid thermal processing such as RTP, spike annealing, and laser annealing.

Thermal processes generally involve delivering energy to a substrate to effect a physical change in the substrate. Each substrate is usually processed in sections, with subsequent sections subjected to the energy treatment until the entire substrate is processed. The energy delivered to each section is controlled so that the substrate is uniformly processed, and successive substrates are uniformly processed.

Delivery of the same energy treatment during each process cycle depends on detecting the power delivered during each process cycle and setting the output level of the energy source. Power measurement is typically performed using power sensors such as pyroelectric detectors, for example thermocouples, and photoelectric detectors, for example photodiodes, which may be incorporated in power meters. Such power meters are used to normalize power delivery by the energy source.

Power measurement by the power meter may drift over time. As the signal returned by the power meter in response to a given condition drifts, energy delivery to substrates may drift, resulting in a drift in process results. There is a need for methods of detecting such changes over time and responding to the changes to preserve process stability of thermal processes.

### SUMMARY

A method of controlling a thermal treatment process for semiconductor substrates is described. A substrate is disposed in a thermal process chamber. A plurality of test locations are identified on the substrate surface, and the test locations are processed with different combinations of energy fluence and exposure duration. A physical property such as reflectivity is measured for each test process, and the data compared to a standard data set. The performance of the process is thus compared to a known physical quantity, and then an adjustment applied to the process power to correct for an average offset, gain, or other inaccuracy in performance of the thermal processing apparatus.

In a method of processing semiconductor substrates, a plurality of substrates may be processed, after which a test such as that described above may be performed to check performance of the thermal processing apparatus. After adjusting the process, substrate processing may resume.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram summarizing a method according to one embodiment.

FIG. 2 is a graph showing an exemplary data set that may be used to practice methods described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In a thermal processing apparatus, radiation is directed toward a substrate to impart energy to the substrate. The radiation may be sampled by a power meter to determine the energy fluence of the radiation, which may then be used to control power output of the energy source. A laser processing apparatus that incorporates such measures is described in U.S. patent application Ser. No. 13/194,552, filed Jul. 27, 2011, which is herein incorporated by reference. The power meter, which may be an energy meter, generates a signal based on a detected property according to a relationship that depends on physical properties of the power meter. Over time, those physical properties may change, so the energy fluence represented by a particular signal changes. If the signal is used to control power output of the energy source, the energy fluence delivered to a substrate over time may drift. For example, an energy source may be controlled to maintain a signal of 5 volts from an energy meter. If the energy required to generate 5 volts from the energy meter increases, the energy output of the energy source will increase to maintain the signal at 5 volts.

The changing relationship between energy fluence and the signal returned by the power meter may be detected by testing a substrate using a range of energy fluences and pulse durations and comparing measured physical properties of the test substrate to known properties of the substrate material. A silicon substrate, or a substrate having a silicon surface, may be used as a test substrate for a thermal process used for treating silicon-containing substrates. A plurality of test locations are defined in the surface of the test substrate, and each test location is subjected to a different combination of energy fluence and exposure duration. Reflectivity of the substrate is measured during each test, and the reflectivity is time-integrated over the duration of a test location treatment. Each test location is processed, and the data is compared to a standard data set. An average offset and/or gain in energy fluence is determined, and the power output of the energy source is adjusted by an amount related to the offset and/or gain. In this way, any drift in the power meter is compensated by a matching adjustment to the power output of the energy source.

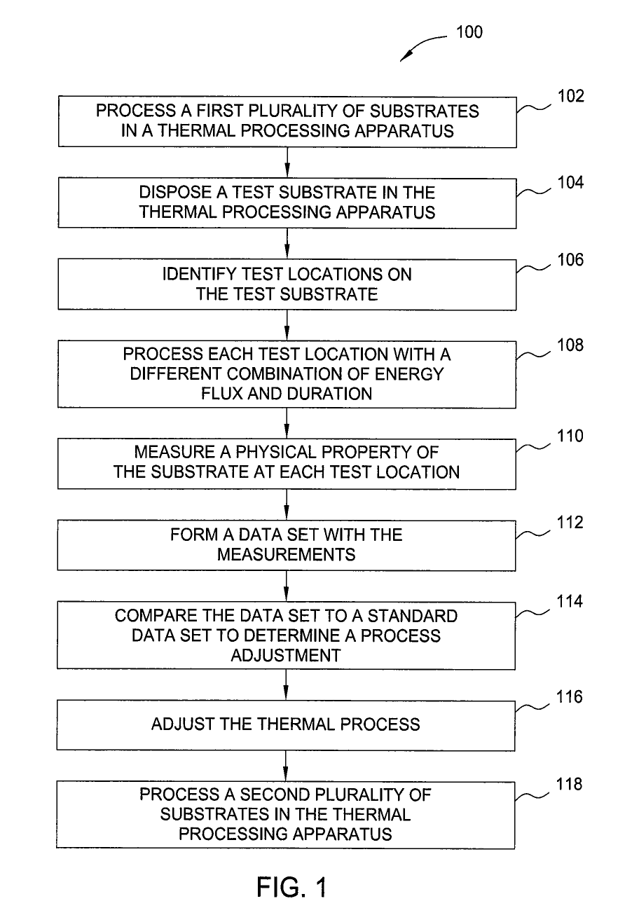

FIG. 1 is a flow diagram summarizing a method 100 according to one embodiment. The method 100 describes use of a power meter test program as part of a thermal treatment process. At 102 a plurality of semiconductor substrates are subjected to a thermal treatment in a thermal processing apparatus. The thermal processing apparatus typically uses a power meter or other power sensor as part of a system to control power and/or energy fluence delivered to substrates during processing. At 104, a substrate is disposed in the thermal processing apparatus. The substrate is usually similar to the production substrates processed in the thermal processing apparatus. For example, if silicon substrates are typically processed in the thermal processing apparatus, the substrate used for testing can be a silicon substrate. The process of FIG. 1 will work for any substrate subject to thermal processing, including semiconductor substrates like silicon, germanium, doped silicon or germanium, combinations of silicon and germanium, and various compound semiconductors, and metal substrates.

Test locations are identified on the substrate at 106 in FIG. 1, and at 108 each test location is processed in the thermal processing apparatus using a different combination of energy fluence and duration. At 110, a physical property of the substrate is measured at each test location in conjunction with the thermal process performed at that location. The data collected at the different energy fluence and duration nodes provides a data set that indicates performance of the thermal processing system. The physical property data are used to relate the measured performance of the thermal processing system to an unchanging physical property. Physical properties that may be used include any property that can be observed to change as energy is injected into the material, such as reflectance, thermal emission, conductivity, magnetic susceptibility, and the like.

In a silicon embodiment, reflectometry data may be used to detect melting of silicon, which is caused by delivery of a fixed energy fluence to a silicon substrate. A low power laser beam is reflected from the test location during thermal processing. Reflectivity of the silicon changes dramatically when the silicon melts. As the melt depth increases, reflectivity changes monotonically until the silicon is melted to the full depth the laser light can penetrate. Reflectometry data for different energy fluence and duration values can be used to determine the process values at which melting began and at which the substrate surface was fully melted, up to the penetration depth capability of the reflectometer.

At 112, the physical property data measured at the different test locations for different energy fluence values and processing durations is formed into a data set. The data set indicates performance of the thermal processing apparatus across a wide process window. The data is compared to a standard data set at 114. Deviations from the standard data set indicate that the energy fluence reported by the power meter has drifted. In the silicon example above, because melt onset of silicon always occurs after the same duration exposure to a given energy fluence, and deviation in the reported energy fluence for that same melt onset at that same duration indicates the power meter is reporting a different energy fluence. An adjustment to the thermal process can then be made at 116 to compensate for the drift in the power meter, and a second plurality of substrates can then be processed at 118. Periodically checking the accuracy of the system in this manner improves process stability across a single substrate as successive zones of the substrate are processed in the thermal processing apparatus, and over successive substrates.

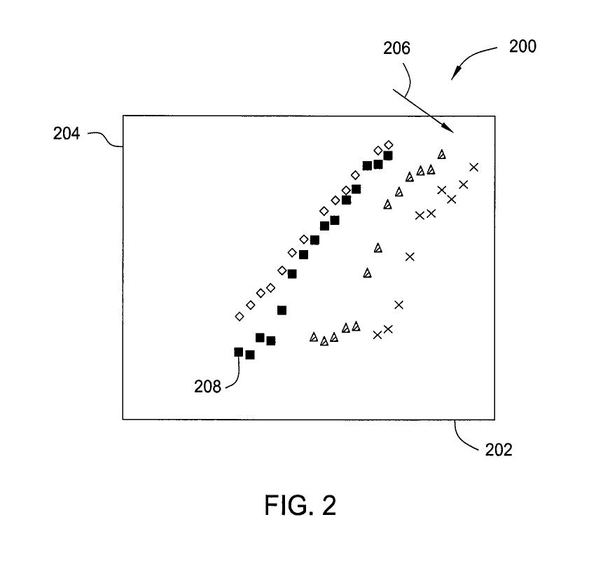

The adjustment to be made to the process is determined as a gain and offset over the entire data set. FIG. 2 is a graph showing a data set 200 that may be generated by the method 100, and may be used to determine a process adjustment. The data set 200 represents a plurality of thermal processes performed at different test locations on a silicon substrate. Axis 202 is energy fluence, increasing to the right. Axis 204 is the integrated reflectivity signal, increasing upward. Each data point represents a different test location. The data define curves showing a reflectivity response at specific processing durations, each curve representing a processing duration. Arrow 206 represents the direction of increasing duration, with curves to the right documenting tests using longer energy pulses.

The data typically collected in a study as described herein indicates the response of an energy meter. The data are collected using a reflectometer that detects laser light reflected from the surface of a substrate during a thermal treatment process. The absolute values of the data points collected therefore depend also on the characteristics of the reflectometer laser detector. Due to characteristics such as sensitivity of the detector, dependence of detector calibration on temperature, and other effects, two reflectometers may repeatably yield different readings under otherwise indistinguishable conditions. It is useful to remove such effects by normalizing the data collected, which amounts to normalizing the ordinate axis in the graph of FIG. 2. Such normalization may be accomplished by comparing the data collected to a standard, reference, or control data set to identify any offset or multiple effects in the ordinate data set.

For example, if a normalization set of data points N are collected under reference conditions (i.e. using a known substrate and a thermal processing apparatus known to be in good control) and compared to a reference set of data points R and a normally distributed offset is demonstrated, an offset may be applied to the ordinate, if desired, to remove artifacts in any test data previously or subsequently collected that are attributable to the reflectometer. If the offset is not normally distributed, a multiple may be applied to determine whether a multiple effect is present. Other standard normalizations, which may be non-linear, may be indicated by applying such normalizations to the reference set R or the normalization set N.

The data set 200 indicates reflectivity changes in the silicon substrate as the substrate is melted in a thermal process. For example, the data subset 208 shows that, prior to melting, increasing energy fluence does not affect reflectivity substantially. As the surface melts, reflectivity changes with the proportion of liquid silicon versus solid silicon. The changes define form a curve representing the reflectivity response of the substrate during the thermal process. If the power meter reporting the energy fluence develops a bias or drift, the observed reflectivity response of the silicon substrate will seem to change, and the response curve will show a deviation from a standard curve. A series of curves may be fit to the data subsets in the two sets of data using a computing device, and an average distance between corresponding curves computed as an energy fluence bias. For a thermal processing apparatus such as the ASTRA® thermal processing system available from Applied Materials, Inc., of Santa Clara, Calif., a fluence adjustment may be provided to a controller to adjust the thermal process, for example by adjusting power input to the energy source of the thermal process, in response to a determined offset or gain of a power meter.

Combinations of energy fluence and duration may be repeated on a substrate during testing, if desired, to improve accuracy, particularly if the number of energy fluence/duration combinations to be tested is less than the number of identified test locations on the substrate. Such repetition may improve the accuracy of the bias determination by indicating repeatability of the reflectometer signal.

It should be noted that reasonable analogs of energy fluence may be substituted. For example, energy flux is related to energy fluence, and a peak energy flux may represent energy fluence if all the pulses used for the test program generally have the same temporal shape. If ramp up and ramp down portions of the energy pulses are short relative to the overall pulse for all pulse durations used for the test, average energy flux, which is fluence divided by duration, may also be used to represent fluence, if desired.

The standard data set used for comparison purposes in the descriptions above may be used to characterize materials. In one method, a substrate of unknown composition may be tested according to any of the methods described herein, and the data set produced by the test program can be compared to a library of standard data sets, as described above, to identify the material of the substrate. Best results are obtained for such a process if the calibration of the power sensor used for the test and the power sensor used to generate the standard data are traceable to the same standard. In other words, if the calibration of the two power sensors was performed using two different processes, those processes should be ultimately traceable to the same original calibrant for best results. Power sensors not traceable to the same calibrant may, nonetheless, be used to characterize materials according to the processes described herein if compositional differences between the two calibrants are small to negligible compared to variation among power sensors in general.

The foregoing describes embodiments of the invention to illustrate and explain the invention, which is broader than the individual embodiments described herein. Other embodiments not described herein that incorporate the invention are intended to be fully covered by the claims that follow.

What is claimed is:

1. A method of controlling a thermal treatment process for semiconductor substrates, comprising:
disposing a substrate in a process chamber;
identifying a plurality of test locations on a surface of the substrate;
determining an energy fluence and exposure duration for each test location;
exposing each test location to a different combination of energy fluence and exposure duration;
measuring an integrated reflectivity of each test location to form a data set;
comparing the data set to a standard data set;
determining a deviation of the data set from the standard data set; and
adjusting the power delivery of the thermal treatment process based on the deviation.

2. The method of claim 1, wherein the measuring the integrated reflectivity of each test location comprises directing a low power laser output toward each test location and measuring an intensity of the reflected light.

3. The method of claim 1, wherein the integrated reflectivity is a time-integrated reflectivity.

4. The method of claim 1, wherein the substrate is a semiconductor substrate.

5. The method of claim 1, wherein the substrate is a silicon substrate.

6. The method of claim 3, wherein the substrate is a silicon substrate and the time-integrated reflectivity is measured by directing a low power laser output toward each test location and measuring an intensity of the reflected light.

7. A method of thermally processing semiconductor substrates, comprising:
performing a thermal treatment on a first plurality of substrates;
checking accuracy of power delivery during thermal processing by applying a plurality of thermal treatments having different energy fluences and durations to a plurality of locations on a substrate and adjusting the power delivery of the thermal process based on the plurality of thermal treatments; and then
performing a thermal treatment on a second plurality of substrates.

8. The method of claim 7, wherein the checking the accuracy of power delivery during thermal processing comprises measuring reflectivity of each of the plurality of locations during the plurality of thermal treatments.

9. The method of claim 8, wherein the checking the accuracy of power delivery during thermal processing further comprises forming a data set with energy fluence, duration, and measured reflectivity during each of the plurality of thermal treatments and comparing the data set to a standard data set.

10. The method of claim 9, wherein the measured reflectivity is a time-integrated reflectivity.

11. The method of claim 10, wherein the power delivery of the thermal process is adjusted based on a gain and/or offset identified from comparing the data set to the standard data set.

12. The method of claim 11, wherein the substrate is a semiconductor substrate.

13. The method of claim 11, wherein the substrate is a silicon substrate.

14. A method of thermally processing a substrate, comprising:
identifying a plurality of test locations on a semiconductor substrate;
identifying a plurality of energy fluences and durations;
selecting a test location from the plurality of test locations;
selecting an energy fluence from the plurality of energy fluences;
selecting a duration from the plurality of durations;
applying energy from an energy source to the test location at the selected energy fluence for the selected duration;
measuring a physical property of the test location while applying the energy to the test location;
repeating the selecting a test location not previously selected, selecting an energy fluence, selecting a duration, applying energy to the test location at the selected energy fluence for the selected donation, and measuring the physical property of the test location until all test locations in the plurality of test locations have been processed;
forming a data set with the energy fluences applied to the test locations, the durations for which each energy fluence is applied, and the measured physical properties of each of the test locations;
comparing the data set to a standard data set; and
controlling the energy source based on the comparison of the data set to the standard data set.

15. The method of claim 14, wherein the physical property is reflectivity.

16. The method of claim 14, wherein measuring the physical property of the test location comprises directing a low power laser output to the test location and measuring a time-integrated reflectivity of the test location.

17. The method of claim 14, wherein the semiconductor substrate is a silicon substrate.

18. The method of claim 14, wherein comparing the data set to the standard data set comprises identifying an average gain and/or offset between the data set and the standard data set.
